(19) United States
(12) Patent Application Publication
(10) Pub. No.: US 2002/0000928 A1
(43) Pub. Date: Jan. 3, 2002

(54) Analogue to digital signal conversion

(76) Inventors: Christian Heyl, Sodra Sandby (SE); Joachim Sjolander, Malmo (SE)

Correspondence Address: JENKENS & GILCHRIST, PC, 1445 ROSS AVENUE, SUITE 3200, DALLAS, TX, 75202, US

(21) Appl. No.: 09/881,955

(22) Filed: Jun. 15, 2001

(30) Foreign Application Priority Data
Jun. 16, 2000 (GB) 0014840.3

(51) Int. Cl. H03M 1/12

(52) U.S. Cl. 341/155

(57) ABSTRACT

An analogue to digital converter has a settable trigger level that generates an interrupt signal for a CPU when a trigger condition is fulfilled.

### FIELD OF THE INVENTION

The present invention relates to analogue to digital signal conversion, and in particular to A to D converters for use in portable electronic devices.

### BACKGROUND OF THE INVENTION

Many portable electronic devices require monitoring of analogue signals by the central processing unit (CPU) of the device, for example to detect predetermined changes in those signals to trigger actions or to control characteristics of the device. Accordingly, as is well known, it is necessary to convert the analogue signal to a digital signal for use by the CPU. FIG. 1 shows schematically a device including a CPU 1 and an analogue to digital converter ADC 2. In previously considered solutions, the A to D converter 2 is provided by an analogue ASIC (application specific integrated circuit) which is controlled by the CPU 1. When the CPU 1 requires determination of the level of an analogue signal, then the CPU controls the ADC 2 so that an analogue input signal 3 is converted to a digital output signal 4. This requires CPU activity, and can therefore increase the power consumed by the CPU. Such a solution also has an impact on time critical processes since the CPU is required to await the output from the ADC 2 before continuing.

In complex systems there are many signals to monitor, some of them change quickly and others slowly. In slowly-changing and steady state signals, there will be many unnecessary A to D conversions, and hence unnecessary increased CPU activity, since for a quick CPU reaction time the frequency of sampling the signal must be increased. In addition, when a signal passes a threshold level there is time lost between the passing of the threshold level and the activation of the ADC by the CPU. This reaction time is naturally dependent upon the sampling frequency of the CPU software.

U.S. Pat. No. 5,731,806 describes an analogue to digital converter for use with a joystick for a computer or computer games system. In such a system, the previous joystick position is compared with the current joystick position. The position of the joystick is indicated by analogue signals converted to respective digital signals, and when the difference between the two positions exceeds a predetermined value, the joystick logic outputs an interrupt to the CPU. The comparison is performed each time the CPU issues a signal requiring an indication from the joystick of movement of that joystick. Accordingly, such a system does not overcome the problem associated with portable electronic devices, namely the increased power consumption of increasing CPU usage, since CPU usage is not reduced to an absolute minimum. In addition, such a device does not measure absolute values, but rather merely measures differences between signals for comparison with a threshold value. Furthermore, there is no provision for triggering on positive or negative edges, since only signal magnitude is considered.

### SUMMARY OF THE PRESENT INVENTION

It is emphasised that the use of the term “comprises” or “comprising” in this specification is taken to specify the presence of stated features, integers, steps or components, but does not preclude the inclusion of one or more additional features, integers, steps or components, or groups thereof.

According to one aspect of the present invention, there is provided a portable electronic device comprising a control unit and an analogue to digital conversion apparatus, wherein the conversion apparatus comprises:

an A to D converter device operable to convert an analogue input signal to a digital output signal;

a threshold register operable to store a digital threshold value;

a comparator device operable to compare the digital output value with the stored digital threshold value to produce a comparison signal, and operable to produce an interrupt signal for transfer to the control unit in dependence upon the comparison signal; and a storage device operable to store the digital output signal.

According to another aspect of the present invention, there is provided a portable electronic device comprising a control unit and an analogue to digital conversion apparatus, wherein the conversion apparatus comprises:

an A to D converter device operable to convert an analogue input signal to a digital output signal;

a threshold register operable to store a digital threshold value; and

a comparator device operable to compare the digital output value with the stored digital threshold value to produce a comparison signal, and operable to produce an interrupt signal for transfer to the controller in dependence upon the comparison signal.

According to another aspect of the present invention, there is provided a method of monitoring an analogue signal in a portable electronic device comprising a control unit and an analogue to digital converter unit, the method comprising:

using the analogue to digital converter:

receiving an input analogue signal;

converting the input analogue signal to an output analogue signal;

comparing the output digital value with a threshold value; and

sending an interrupt signal to the control unit in dependence upon the result of the comparison.

### BRIEF DESCRIPTION OF THE DRAWINGS

FIG. 1 is a schematic diagram showing the prior art A to D converter apparatus; and

FIG. 2 is a schematic diagram of an embodiment of the present invention.

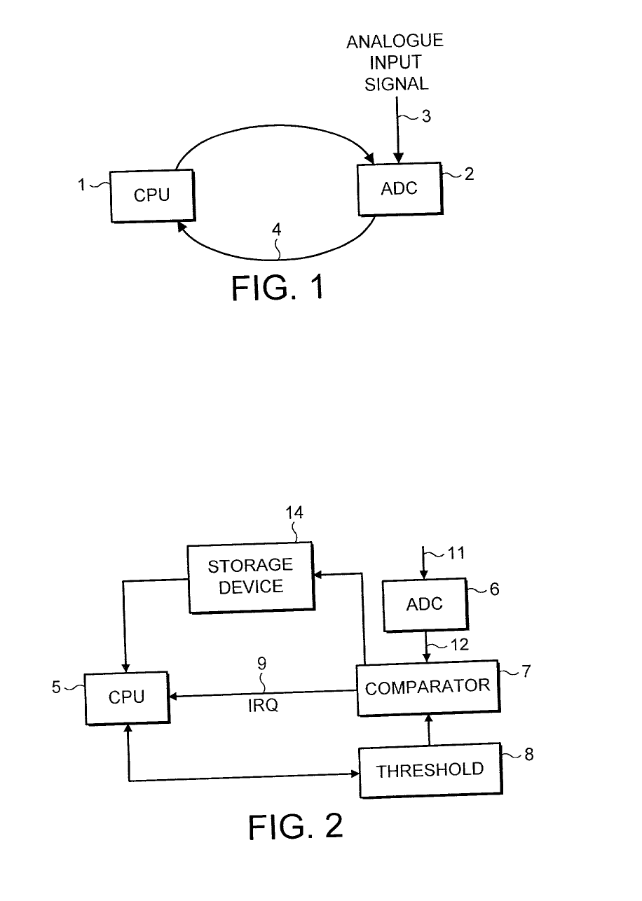

### DETAILED DESCRIPTION OF THE PREFERRED EMBODIMENT

FIG. 2 illustrates an analogue to digital converter apparatus embodying the present invention and comprising a CPU 5, an A to D converter ADC 6, a comparator 7 and a threshold storage device 8. The apparatus shown in FIG. 2 is suitable for monitoring an analogue input signal 11. The analogue input signal 11 is supplied to the ADC 6 which operates continuously to convert the analogue signal to a digital signal 12. The digital signal 12 is compared by the comparator 7 with a threshold value stored in the threshold storage device 8. The comparator operates to produce an interrupt request IRQ 9 for supply to the CPU 5 when the digital value 12 meets the threshold criterion determined by the threshold value 8. The threshold value 8 can be programmed by the CPU 5.

Such an apparatus can reduce the amount of CPU activity to monitor an analogue signal, since the CPU is only used when the analogue signal meets the threshold criterion. This can also promote faster reaction time, since the IRQ 9 is produced as soon as threshold criterion is fulfilled. The handling of the IRQ can be determined by the software controlling the CPU, and so the device in which the system is installed can react appropriately. Lower CPU activity leads to lower power consumption, and lower unnecessary CPU activity means that a higher proportion of the CPU's time can be spent on time critical applications.

The criterion for determining production of the IRQ 9 can simply be that the digital signal 12 exceeds the threshold value. Alternatively, the threshold value could be a lower value that triggers an IRQ 9 when the digital signal drops below the value. Instead of simply setting a threshold value for comparison with the digital signal 12, it is possible to determine the slope of the digital signal 12 (and the analogue signal 11) whilst passing a threshold value so that it may be determined whether the analogue signal is rising or falling.

Also illustrated in FIG. 2 is a storage device 14. This is provided in a preferred embodiment of the invention for storing the digital output value which is compared with the threshold value. Preferably, the actual digital value that causes an interrupt to be produced is stored in the storage device 14. The value that is stored in the device 14 is accessible by the control unit. The storing of the value that causes the interrupt enables the CPU to analyses the cause of the interrupt. For example it is possible that a momentary change in value (or “glitch”) may occur that causes an interrupt to be produced, but does not in fact indicate the occurrence of a genuine interrupt condition.

A converter embodying the present invention can have several uses in a portable device. For example, when charging the battery of the device, it is possible to interrupt the CPU only when the required voltage or current value is reached. Monitoring of the battery presence and/or level can be achieved; the converter can keep track of different battery levels to manage battery consumption or measure remaining capacity of the battery. He threshold value could then indicate a battery threshold value such as state of charge that causes an interrupt condition to be caused. For example, the threshold value may indicate when the battery is at full charge, or when the battery is at an undesirably low charge.

Temperature monitoring, and in particular alarm condition monitoring, can be easily achieved with low CPU intervention. In the case of temperature monitoring, a threshold temperature value, for example indicating a high operating temperature, can be used as the basis of the comparison with the input temperature value.

In addition, such a converter can be used to detect connection of accessories to the device, simply by monitoring connection line levels and comparing these to threshold levels. It is desirable that different accessories have different line levels associated with them. In this way it is possible to determine the identity of the accessory that is connected to the device. Furthermore, and particularly when more than one accessory is connected, it is possible to differentiate between different types of control signals depending upon the level of the signals. Ths then allows the provision of analogue and control signals on a single line.

It will be appreciated that any portable electronic device could make use of a converter embodying the present invention. For example, mobile telephones and personal digital assistants (PDAs) could make use of the present invention.

1. A portable electronic device comprising a control unit and an analogue to digital conversion apparatus, wherein the conversion apparatus comprises:
an A to D converter device operable to convert an analogue input signal to a digital output signal;
a threshold register operable to store a digital threshold value;
a comparator device operable to compare the digital output value with the stored digital threshold value to produce a comparison signal, and operable to produce an interrupt signal for transfer to the control unit in dependence upon the comparison signal; and
a storage device operable to store the digital output signal.

2. A device as claimed in claim 1, wherein the comparator device includes means for determining the slope of the analogue input signal, such that the comparison signal is indicative of this slope.

3. A device as claimed in claim 1 or 2, wherein the threshold value is programmable by the control unit.

4. A device as claimed in claim 1, 2 or 3, wherein the threshold register is accessible by the control unit, and wherein the control unit is operable to store a required threshold value in the threshold register.

5. A device as claimed in claim 1, wherein the storage device is operable to store the digital output signal that results in an interrupt signal.

6. A device as claimed in claim 1, wherein the storage device is accessible by the control unit, and the control unit is operable to retrieve the digital output value from the storage device.

7. A device as claimed in any one of the preceding claims, wherein the analogue input signal is indicative of a temperature, and the threshold value is indicative of a threshold temperature.

8. A device as claimed in any one of claims 1 to 6, wherein the analogue input signal is indicative of a state of charge of a battery of the device, and the threshold value is indicative of a threshold battery charge level.

9. A device as claimed in any one of the preceding claims, wherein the control unit is operable, upon receipt of the interrupt signal from the comparator device, to perform at least one predetermined instruction.

10. A device as claimed in any one of the preceding claims, including an accessory device , and wherein the analogue input signal is indicative of the identity of the accessory device.

11. A device as claimed in any one of claims 1 to 10, including an accessory device, and wherein the analogue input signal is indicative of the status of the accessory device.

12. A device as claimed in any one of the preceding claims, wherein the interrupt signal is produced when the comparison signal indicates that the digital output value exceeds the threshold value.

13. A device as claimed in any one of claims 1 to 12, wherein the interrupt signal is produced when the comparison signal indicates that the digital output value is less than the threshold value.

14. A device as claimed in any one of claims 1 to 12, wherein the interrupt signal is produced when the comparison signal indicates that the digital output value is rising with respect to the threshold value.

15. A device as claimed in any one of claims 1 to 12, wherein the interrupt signal is produced when the comparison signal indicates that the digital output value is falling with respect to the threshold value.

16. A device as claimed in any one of the preceding claims, wherein the device is a mobile telephone.

17. A device as claimed in any one of claims 1 to 16, wherein the device is a portable digital assistant (PDA).

18. A method of monitoring an analogue signal in a portable electronic device comprising a control unit and an analogue to digital converter unit, the method comprising:
using the analogue to digital converter:
receiving an input analogue signal;
converting the input analogue signal to an output digital signal;
comparing the output digital value with a threshold value; and
sending an interrupt signal to the control unit in dependence upon the result of the comparison, wherein the digital output value is stored for retrieval.

19. A method as claimed in claim 18, wherein the digital output value which causes an interrupt signal is stored.

20. A method as claimed in claim 18 or 19, wherein the stored value is accessible by the control unit.

21. A method as claimed in any one of claims 18 to 20, wherein the interrupt signal is sent to the control unit if the digital output value exceeds the threshold value.

22. A method as claimed in any one of claims 18 to 20, wherein the interrupt signal is sent to the control unit if the digital output value is less than the threshold value.

23. A method as claimed in any one of claims 18 to 20, wherein the interrupt signal is sent to the control unit if the digital output signal is falling with respect to the threshold signal.

24. A method as claimed in any one of claims 18 to 20, wherein the interrupt signal is sent to the control unit if the digital output value is rising with respect to the threshold value.

25. A method as claimed in any one of claims 18 to 24, wherein the threshold value is set by the control unit.

26. A method as claimed in any one of claims 18 to 25, wherein the device is a mobile telephone.

27. A method as claimed in any one of claims 18 to 25, wherein the device is a portable digital assistant (PDA).
